(19) United States
(12) Patent Application Publication
(10) Pub. No.: US 2006/0003731 A1
(43) Pub. Date: Jan. 5, 2006

(54) Multimedia player receivable satellite signals

(76) Inventor: Juen Tien Peng, Chung Li (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/880,579

(22) Filed: Jul. 1, 2004

(51) Int. Cl. H04B 1/06; H05K 11/00; H04B 1/08

(52) U.S. Cl. 455/344; 455/347

(57) ABSTRACT

A multimedia player receivable satellite signals includes a CPU, an improved satellite antenna connected to the CPU for receiving the satellite signals, a CD-ROM connected to the CPU for reading a CD received therein, an operation interface connected to the CPU, an LCD connected to the CPU for video output, a speaker connected to the CPU for audio output, and a replaceable battery pack connected to the CPU as a power supplier.

### BACKGROUND OF THE INVENTION

1. Field of the Invention

The present invention relates to a multimedia player, and particularly to a multimedia player receivable satellite signals.

2. Prior Art

A television (TV) set is used to receive program signals and play program. In accordance with transmission manner of program signals, the TV is classified to three types, that's traditional radio-vision, cable TV and satellite TV. As it is well known, as to the traditional radio-vision, program signals can be received only within a narrow scope, and program's available choices are limited. Though the cable TV can receive quite a lot of programs, it is complicated to construct transmitting cable. The satellite TV can overcome the above shortcomings of the traditional radio-vision and the cable TV. Furthermore, the satellite TV can transmit audio and video (AV) signals with higher quality form.

A storage media which is a compact disc (CD) provides a new selection of watching and hearing with higher quality and larger capacity. Currently, the storage media may be also a CD/R, a VCD, a DVD, or a DVD/R.

Oftentimes, a satellite TV and a multimedia player are arranged together to have their functions. FIG. 1 shows conventional multimedia configuration 2. When an audience 1 wants to watch satellite TV, a satellite antenna 21 and a top box 22 are required with the top box 22 being connected to a display 24 for video output and a megaphone 25 for audio output. When the audience 1 wants to play CD, a CD player 23 is connected to the display 24 and the megaphone 25 and then turned on. Similarly, when the audience 1 wants to use other format multimedia device 3, the other format multimedia device 3 is connected to the display 24 and the megaphone 25. Therefore, the conventional multimedia configuration 2 occupies large space and is not portable. Furthermore, it is complicated to connect the above components or modules and so it is not convenient in use.

Additionally, the multimedia configuration 2 need an external power supply device 4 to supply power. The external power supply device 4 may be a home electrical socket, a mini-type dynamo, or a vehicle battery. Since the components or modules of the multimedia configuration 2 are separated, many power wires are required to connect to the external power supply device 4, which results in inconvenience in use.

### SUMMARY OF THE INVENTION

Accordingly, an object of the present invention is to provide a multimedia player receivable satellite signals which has functions of a satellite TV and a CD player.

Another object of the present invention is to provide a multimedia player receivable satellite signals which is portable and convenient in use.

Another object of the present invention is to provide a multimedia player receivable satellite signals which has a plurality of I/O ports for expanding functions thereof.

To achieve the above-mentioned objects, a multimedia player receivable satellite signals in accordance with the present invention includes a CPU, an improved satellite antenna connected to the CPU for receiving the satellite signals, a CD-ROM connected to the CPU for reading a CD received therein, an operation interface connected to the CPU, an LCD connected to the CPU for video output, a speaker connected to the CPU for audio output, and a battery pack connected to the CPU as a power supplier.

Other objects, advantages and novel features of the present invention will be drawn from the following detailed embodiment of the present invention with attached drawings, in which:

### BRIEF DESCRIPTION OF THE DRAWINGS

FIG. 1 is a chart showing a conventional multimedia configuration;

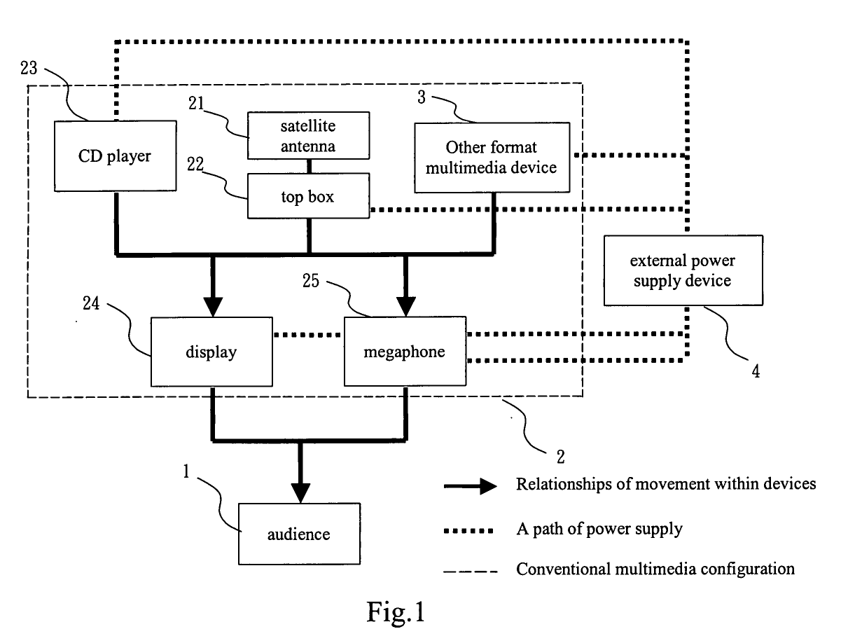

FIG. 2 is a schematic view of a multimedia player receivable satellite signals of the present invention; and

FIG. 3 is a chart showing the multimedia player receivable satellite signals of the present invention.

### DESCRIPTION OF THE PREFERRED EMBODIMENT

A multimedia player receivable satellite signals of the present invention is combined with a CD multimedia player and an antenna for receiving satellite TV signals and is configured to be portable and convenient in use.

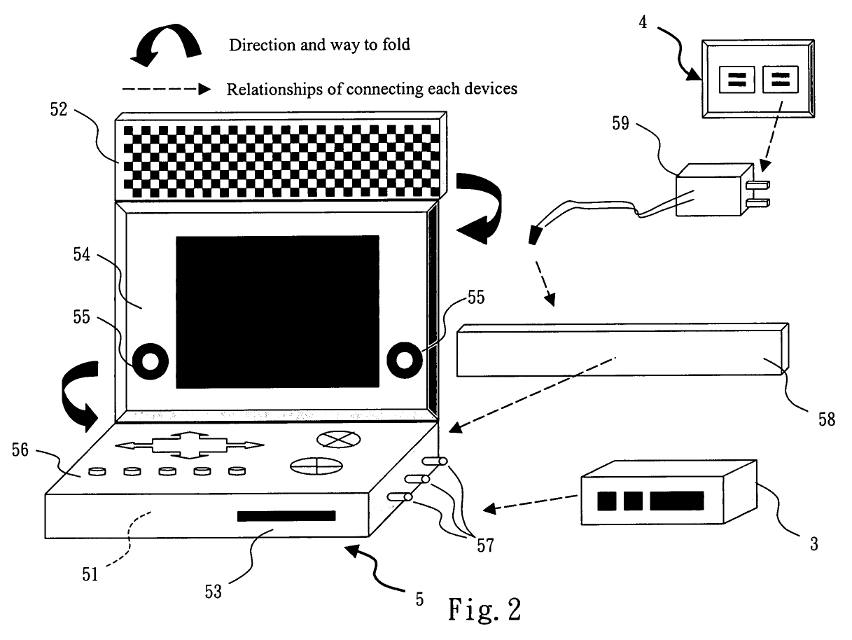

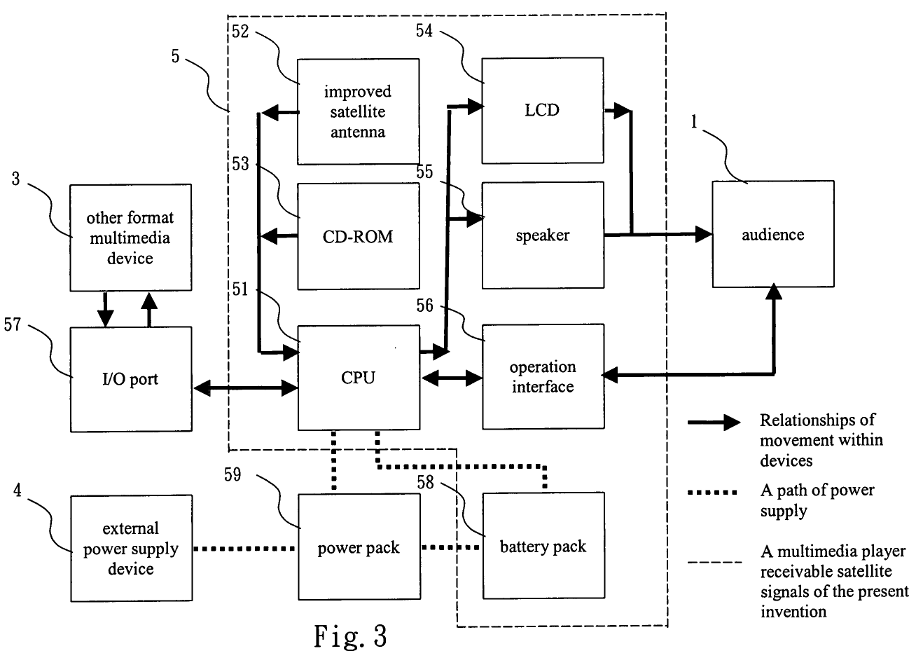

Referring to FIG. 2, the multimedia player 5 receivable satellite signals of the present invention employs a CPU 51 to control other components or modules thereof. An improved satellite antenna 52 and a CD-ROM 53 are employed as audio and video (AV) input devices. The improved satellite antenna 52 is flat and foldable. An LCD 54 is employed as a video output device instead of a traditional display and connected to the improved satellite antenna 52. When the LCD 54 is not in use, the LCD 54 can be folded to a closed position thereby protecting the display panel and reducing occupying space. A speaker 55 is employed as an audio output device instead of a traditional megaphone and disposed near the LCD 54 for saving space. As shown in FIG. 3, an audience 1 may input a command through an operation interface 56 for selecting one of programs or one of functions of the multimedia player 5. The operation interface 56 can convert and transmit the command signal to the CPU 51 which controls operation of corresponding components or modules in accordance with the command signal.

As shown in FIG. 3, the CPU 51 has a function of a conventional top box which is capable to code and encode satellite signals. The improved satellite antenna 52 receives satellite signals and then transmits the satellite signals to CPU 51 for processing just as a traditional satellite antenna plus a top box which used in a satellite TV. Thus, the multimedia player 5 of the present invention does not need the conventional top box 22, which results in reducing cost and saving occupying space thereof. Similarly, the multimedia player 5 of the present invention replaces a conventional CD player 23 with a CD-ROM 53 connected to the CPU 51. Therefore, multimedia signals with different formats may be input to the CPU 51 for processing and then outputting multimedia signals with same format. Thus, the multimedia player 5 of the present invention has functions of a satellite TV and a CD player.

As shown in FIG. 2, an external battery pack 58 is connected to the multimedia player 5 as a power supplier to the multimedia player 5. The battery pack 58 is replaceable and so the multimedia player 5 can be supplied with continuous power through replacing the battery pack 58 when used up. Thus, the multimedia player 5 can work without an external power supply device 4 through the battery pack 58. Furthermore, referring to FIG. 2, a power pack 59 is provided to connect between the battery pack 58 and the external power supply device 4 for charging the battery pack 58. Of cause, the power pack 59 can connect to and supply power to the multimedia player 5 directly. The external power supply device 4 may be a home electrical socket, a mini-type dynamo, or a vehicle battery.

As described above, the signal input device such as the improved satellite antenna 52 and the CD-ROM 53, the signal output device such as the LCD 54 and the speaker 55, and the body of the multimedia player 5 such as the CPU 51, the operation interface 56 and the battery pack 58, are miniaturized and lighten thereby reducing volume and weight of the multimedia player 5 of the present invention. Thus, the multimedia player 5 of the present invention is convenience and portable.

Referring to FIG. 3, the multimedia player 5 of the present invention includes a plurality of I/O ports 57 at one side thereof for connecting to other format multimedia devices 3 thereby expanding functions of the multimedia player 5. As mentioned above, the CPU 51 has functions of coding and encoding for different formats. Therefore, multimedia signals with different formats may be input to the CPU 51 for processing and then outputting multimedia signals with same format. Thus, the multimedia player 5 of the present invention has expanding functions.

It is understood that the invention may be embodied in other forms without departing from the spirit thereof. Thus, the present examples and embodiments are to be considered in all respects as illustrative and not restrictive, and the invention is not to be limited to the details given herein.

1. A multimedia player receivable satellite signals, comprising:
a CPU;
a satellite antenna, connected to the CPU for receiving the satellite signals;
a CD-ROM, connected to the CPU for reading a CD received therein;
an operation interface, connected to the CPU;
an LCD, connected to the CPU for video output;
a speaker, connected to the CPU for audio output; and
a battery pack, connected to the CPU as a power supplier.

2. The multimedia player receivable satellite signals as claimed in claim 1, wherein the multimedia player is portable.

3. The multimedia player receivable satellite signals as claimed in claim 1, wherein the multimedia player includes a plurality of I/O ports for connecting to other format multimedia devices.

4. The multimedia player receivable satellite signals as claimed in claim 1, wherein the CPU has functions of coding and encoding.

5. The multimedia player receivable satellite signals as claimed in claim 1, wherein the satellite antenna is flat and foldable and is disposed at the LCD.

6. The multimedia player receivable satellite signals as claimed in claim 1, wherein the CD-ROM is readable a CD, a CD/R, a VCD, a DVD or a DVD/R.

7. The multimedia player receivable satellite signals as claimed in claim 1, wherein the battery pack is replaceable.

8. The multimedia player receivable satellite signals as claimed in claim 1, wherein a power pack is optional and connected between the battery pack and an external power supply device for charging the battery pack.

9. The multimedia player receivable satellite signals claimed in claim 8, wherein the power pack can be connected to and supply power to the multimedia player directly.

10. The multimedia player receivable satellite signals claimed in claim 8, wherein the external power supply device is a home electrical socket, a mini-type dynamo, or a vehicle battery.

11. The multimedia player receivable satellite signals claimed in claim 9, wherein the external power supply device is a home electrical socket, a mini-type dynamo, or a vehicle battery.
